(19) United States
(12) Patent Application Publication
(10) Pub. No.: US 2002/0071577 A1
(43) Pub. Date: Jun. 13, 2002

(54) Voice controlled remote control with downloadable set of voice commands

(76) Inventors: Wim Lemay, Leuven (BE); Joerg Nowack, Leuven (BE)

Correspondence Address: Corporate Patent Counsel, U.S. Philips Corporation, 580 White Plains Road, Tarrytown, NY, 10591, US

(21) Appl. No.: 09/933,842

(22) Filed: Aug. 21, 2001

(30) Foreign Application Priority Data
Aug. 21, 2000 (EP) 00202919.7

(51) Int. Cl. H04R 3/00; H03G 3/20

(52) U.S. Cl. 381/110; 704/275; 367/198

(57) ABSTRACT

A remote control for controlling an electronic device, comprising a microphone for detecting spoken command data, a processor for executing a speech recognition algorithm using template data to recognize spoken commands detected by said microphone and for controlling said electronic device, a receiver to receive template data from an external storage or network to enable the remote control to recognize spoken commands, a memory to store said selected and received template data.

The present invention generally relates to a remote control having a speech interface and, more particular, to a remote control for a television set or an electronic device for viewing and gathering information and movies.

The number of features which have to be implemented in a remote control such as an implemented speech recognition are continuously increasing. Today a remote control does not control only one electronic device. Instead one remote control is used to control separate electronic devices like the television set, the VCR and the satellite dish receiver. Those electronic devices are becoming more and more sophisticated by implementing more valuable features like e.g. teletext and internet communication possibilities. Therefore the number of commands executable by a remote control increases continuously, too. The increase of features and commands has generally resulted in more and more keys on the key-board which make the remote control big and unwieldy.

Speech recognition seems to be the solution for the above mentioned problem. The problem with speech recognition itself is that the speech recognition algorithm is very memory consuming. Therefore the remote control is only capable of recognizing a few spoken commands. There has recently been developed a voice-operated remote control system which employs voice control commands instead of control commands entered through keys. The voice-operated remote control system has a microphone mounted on a transmitter for converting a voice command into an electric voice signal, and a speech recognition LSI (Large Scale Integration) circuit for generation a remote control signal which corresponds to a voice pattern represented by the voice signal. The remote control signal thus generated is transmitted to a receiver in a controlled electronic device. In the system, standard pattern data corresponding to voice commands given by the operator are registered in advance. This system has a speaker-independent recognition and is described in U.S. Pat. No. 5,774,859. For the speaker-independent recognition system, templates are already stored in the memory of the speech recognizer (“Pre-trained”). The templates are normally obtained by averaging over a huge number of speakers, covering different pitches, dialects etc. The big advantage of this solution is, that different users can use the voice commands. The drawbacks are the lack of personalization and the fixed language. The commands are selected by the remote control manufacturer. This might be convenient for standard commands such as “mute”, “volume up” or “channel one”, but it would not allow users to choose a name of a macro. When the commands are pre-trained, which means that the language is fixed, different remotes have to be produced for different countries, leading to a high and expensive diversity.

Another concept is the speaker-dependent recognition. Such a remote control is shown in U.S. Pat. No. 5,199,080. The voice-operated remote control system which transmits a remote control signal in response to a voice command, which was recognized by the implemented speech recognition. The speech recognition circuit has a standard pattern data storage unit for storing a plurality of standard pattern data with respect to each of voice commands. The input voice command is compared with the plural standard pattern data for accurate speech recognition. The system includes a learning unit for automatically updating the stored standard pattern data in response to a change in pattern data of a newly entered voice command. The system can also be trained for newly spoken commands. The major advantage of speaker-dependent recognition such as the system described in the U.S. Pat. No. 5,199,080 is that the user can train the words he wants to use as voice commands in any language he wants. Typically, this consists in pronouncing a word twice. The speech recognizer then extracts features from the word captured and stores the pattern as template in a non-volatile memory. Another advantage of speaker-dependent recognition is a high degree of personalization. The speech recognizer will recognize the commands of the user who trained them with very high reliability. But it will almost always reject the same commands pronounced by another speaker. The disadvantages of speaker-dependent recognition are that the system has to be trained before being able to use voice commands which is always very time consuming and that it does not allow different users to use the remote control such as family members. Training the remote control by several users is not possible because each trained word uses up the limited memory space.

The present invention adds a speech recognition interface to a remote control which combines the advantages of speaker-dependence and speaker-independence speech recognition.

A complete voice database might for instance runs on a PC, TV-set, Set-Top-Box (STB) or is accessible through a network e.g. the internet or any other wide area network. The database can be stored on a compact disk (CD-ROM) or other storage medium which might be supplied with the remote control. In this case, downloading will take place via a local download device, such as a PC, TV-set, Set-Top-Box (STP) or the controlled electronic device.

Using a network to access the database, the templates are first retrieved from the network via an access device, like the controlled electronic device or a PC, TV-set, Set-Top-Box (STB), and then downloaded—possibly after having been distributed via a local communication system from the Internet access device to the download device—to the remote control.

The database is like a multi-language dictionary, storing all kinds of different commands or words. With a convenient user interface, with search function etc., the user can select a set of words from the dictionary of his preferred language. The database features a database of voice templates and looks up the acoustic templates of the words selected. These templates can then be transferred to the remote control by a wired or wireless link. Instead of selecting the words from a PC-based dictionary software, it is also possible to use an internet service-database which might be displayed by the controlled television set. The needed voice commands can then be selected through the remote control and are then transferred from the television set which receives the template data through the internet to the remote control.

The advantages of the present invention are that the user has a high degree of freedom to quickly customize the remote control by selecting a language, choosing words, changing words. The user can always or automatically download the most sophisticated templates for his needed voice commands. The system is a speaker-independent system, that means all family members can use the selected voice commands without training the speech recognition. The remote control can be sold as an “empty” device that is identical in all countries.

It is another aspect of the invention that the user can download an alphanumeric representation of the word, which belongs to one or more voice templates, which can be displayed on the LCD of the remote control. This might help the user to scroll through the list of trained commands, to erase certain commands that are no longer needed.

The above objects, features and advantages of the present invention will become more apparent from the following description when taken in conjunction with the accompanying drawings in which preferred embodiments of the present invention are shown by way of illustrative examples.

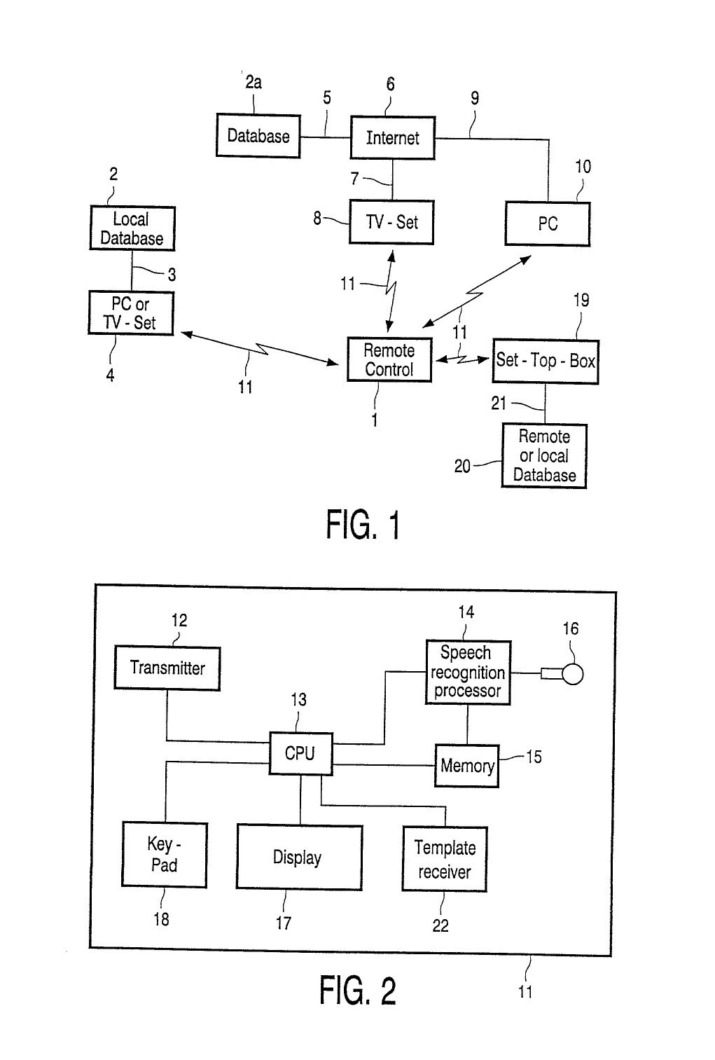

FIG. 1 is a,block diagram of a programmable remote control;

FIG. 2 is a detailed block diagram of the programmable remote control.

FIG. 1 shows a block diagram of the programmable remote control 1. Programmable means that the a set of templates (data) can be downloaded from a database 2, 2a or 20 into the memory of the remote control 1 to enable the remote control 1 to recognize special spoken commands. The programming can be done through a PC 4 which stores the database 2 on a local storage memory like a compact disk (CD) or a hard drive. The PC 4 receives the data from the database 2 through a data bus 3. The user can select through a convenient user interface, e.g. a program which runs on the PC 4, a set of words which represent the spoken commands and link them to signals which should be generated and transmitted by the remote control to a certain electronic device after the speech recognition has recognized said spoken commands. The template data can be transferred from the PC 4 to the remote control 1 by a wireless link 11 using infrared light or by a transmission cable (not shown).

Instead of using a local database the database 2a, 20 can be an external and accessed through the internet and/or telephone lines 9 or other communication channels like TV-broadcasting 7, 21. The items of the database 2 can be selected of a remote PC 10, TV-Set 8 or a Set-Top-Box 19 which is controlled by the programmable remote control 1. The communication between the PC 10, TV-Set 8 or Set-Top-Box 19 is realized wireless, indicated by reference number 11.

Many different arrangements may be utilized to program the remote control 1. It is possible that the stored voice activatable commands of the remote control can be displayed by the display of the remote control itself to erase, add or change the links and commands. It is also possible that the stored voice activatable commands of the remote control can be displayed on the PC 4, 10 or the television set 8. Therefore the stored data is first transferred to the used displaying device. After pressing a certain key of the remote control or a special spoken command. The template data of this special command might not be erasable through the user. After re-programming the set of detectable commands the new template data and if wanted the alphanumeric representations for each detectable spoken command is transferred in the memory of the remote control 1. It is obvious that the template data of those-detectable commands which have not been changed are not transferred for shortening the time needed for transmitting the template data.

FIG. 2 shows a detailed block diagram of the programmable remote control 1. The remote control comprises a transmitter unit 12 which is used for wirelessly transmitting remote control commands to the controlled electronic device such as a TV-set, VCR, Set-Top-Box or a PC using infra-red (IR) or RF. The remote control can comprise a separate template receiver 22, which might also operate wirelessly, e.g. via IR or RF. The remote control receives the template data with the template receiver 22 from the external database. In another preferred embodiment of the invention the remote control uses one transmitter 12 to receive the template data and to transmit control commands to the controlled electronic device.

The operation of the remote control 1 is controlled by a central processing unit (CPU) 13. The received template data and additional data like the alphanumeric representations for the detectable spoken commands are stored in the memory 15 by the CPU 13. The CPU 13 generates remote signals for controlling external electronic devices corresponding to a voice pattern represented by a voice signal which is detected by the microphone 16 and analyzed by the speech recognition processor 14. The speech recognition processor 14 compares the voice patterns with the stored template data for detecting the spoken commands. The remote control 1 can comprise a key-pad 18 and a display 17.

The invention may be embodied in other specific forms without departing from the spirit or essential characteristics thereof. The present embodiments are therefore to be considered in all respects as illustrative and not restrictive.

1. Remote control for controlling an electronic device, comprising:
a microphone for detecting spoken command data;
a processor for executing a speech recognition algorithm using template data to recognize spoken commands detected by said microphone and for controlling said electronic device;
a receiver to receive template data from an external database to enable the remote control to recognize spoken commands;
a memory to store said selected and received template data.

2. Remote control according to claim 1, wherein the database is accessible by an access device like a PC, TV-Set, Set-Top-Box or directly by the remote control.

3. Remote control according to claim 2, wherein the access device has a storage device or memory for storing the database.

4. Remote control according to claim 2, wherein the database is accessible via a network, like the internet or any other wide area network by the access device.

5. Remote control according to claim 2, 3 or 4, wherein new template data needed to recognize new spoken commands, are first selected out of a group of commands stored in the database, and then downloaded and stored in the remote control.

6. Remote control according to claim 5, wherein the database can be displayed by a television set which is linked to the internet and that the selected templates are downloaded through the internet and send wireless from the television set to the remote control.

7. Remote control according to claim 1, wherein alphanumerical representations for each detectable spoken command are stored in a memory of the remote control.

8. Remote control according to claim 7, wherein the remote control comprises a display to display said alphanumerical representations of the detectable spoken commands.

9. Remote control according to claim 8, wherein the user can scroll through the displayed list of detectable spoken commands and delete no longer needed commands, whereby the affiliated template data is erased out of said memory.

10. Remote control according to claim 1 or 2, wherein said electronic device is a television set, Set-Top-Box, VCR or the access device;

11. Remote control according to claim 1, wherein said selectable commands are powering on or off said electronic device, tuning said electronic device to a channel, increasing and decreasing volume;

12. Remote control according to claim 1, wherein each said template data can be linked to a special command which can be executed by the remote control.

13. Method for downloading template data from an external database into a memory of a remote control in accordance with one of the previous claims comprising the following steps:
a) needed template data to recognize new spoken commands is selected out of a group of commands stored in a database;
b) the needed template data is then transmitted from the database to the remote control and stored in the remote control.

14. Method according to claim 13, wherein the template data is supplied via a network, e.g. the Internet or any other wide area network.
